(19) United States
(12) Patent Application Publication
(10) Pub. No.: US 2022/0418087 A1
(43) Pub. Date: Dec. 29, 2022

(54) MULTILAYERED FLEXIBLE PRINTED CIRCUIT, METHOD FOR MANUFACTURING THE SAME, AND APPLICATION THEREOF

(71) Applicant: iCare Diagnostics International Co. Ltd., New Taipei City (TW)

(72) Inventors: KAI YANG, New Taipei (TW); CHUN-YU LIN, New Taipei (TW); BI-SHENG JANG, Tu-Cheng (TW); SHIH-HSUN MA, New Taipei (TW); YU-MIN WANG, New Taipei (TW); BEEN-YANG LIAW, New Taipei (TW); LIEN-HSIANG PAN, New Taipei (TW); SHIN-SHIAN LIOU, New Taipei (TW); CHIEN-YU GU, New Taipei (TW); CHUNG-JEN HSIEH, New Taipei (TW)

(21) Appl. No.: 17/566,189

(22) Filed: Dec. 30, 2021

(30) Foreign Application Priority Data
Jun. 29, 2021 (CN) 202110729574.2

(51) Int. Cl. H05K 1/02; H05K 1/11; H05K 3/12

(52) U.S. Cl. CPC H05K 1/028; H05K 1/11; H05K 3/1283; H05K 2201/095

(57) ABSTRACT

A method for manufacturing a bending-tolerant multilayered flexible circuit board (FPC) suitable for use in a disposable biosensor chip includes manufacturing and bending a single-sided FPC. The single-sided FPC includes a base layer, a wiring layer, and through holes. The wiring layer includes first and second wiring areas. A first bending area is formed between each first wiring area and the corresponding second wiring area, the through holes forming an easy bending line. The second wiring area is bent relative to the first wiring area along the bending line to obtain the multilayered FPC.

### FIELD

The subject matter relates to flexible printed circuits, and more particularly, to a multilayered flexible printed circuit, a method for manufacturing the multilayered flexible printed circuit, and an application of the multilayered flexible printed circuit.

### BACKGROUND

Biosensor chips are used in many portable disease detection devices (such as nucleic acid detection device and blood glucose detection device). The flexible printed circuit (FPC) is a main component of the biosensor chip.

However, the FPC has poor flexibility. When a FPC is bent, warpage may occur, and a circuit may be easily separated from a base layer in the area which is bent. Furthermore, the biosensor chip and the FPC therein are made to be disposable, even though these components have high values, since the manufacturing process of the FPC is complex and costly in the portable disease detection device. There is room for improvement in the art.

### BRIEF DESCRIPTION OF THE DRAWINGS

Implementations of the present technology will now be described, by way of example only, with reference to the attached figures.

FIG. 1 is a cross-sectional view of an embodiment of a base layer of a single-sided flexible printed circuit (FPC) according to the present disclosure.

FIG. 2 is a top plan view of an embodiment of a single-sided FPC according to the present disclosure.

FIG. 3 is a cross-sectional view of a bending area of the single-sided FPC of FIG. 2.

FIG. 4 is a bottom plan view of the single-sided FPC of FIG. 2.

FIG. 5 is a front perspective view of the single-sided FPC of FIG. 2 after bending.

FIG. 6 is a rear perspective view of the single-sided FPC of FIG. 2 after bending.

FIG. 7 is a top plan view of an embodiment of a multilayered FPC according to the present disclosure.

FIG. 8 is a bottom plan view of the multilayered FPC of FIG. 7.

FIG. 9 is a diagram showing range of different resistances in different single-sided FPCs.

FIGS. 10A, 10B, 10C, and 10D are diagrams showing change in resistance in different single-sided FPCs before and after being bent.

FIGS. 11A, 11B, 11C, and 11D are photos of different single-sided FPCs after bending.

FIGS. 12A, 12B, and 12C are photos of a single-sided FPC before and after being bent.

FIG. 13 is a diagram showing percentage changes of resistance in a single-sided FPC before and after forming through holes in the bent area.

FIG. 14 is a diagram showing change in resistance in two single-sided FPCs with different line widths.

FIG. 15 is a diagram showing change in resistance in another two single-sided FPCs with different line widths.

FIG. 16 is a diagrammatic view of an embodiment of a detection chip.

FIG. 17 is a cross-sectional view of the detection chip.

FIG. 18 is a flowchart of an embodiment of a method for manufacturing the multilayered FPC in FIG. 7.

### DETAILED DESCRIPTION

It will be appreciated that for simplicity and clarity of illustration, where appropriate, reference numerals have been repeated among the different figures to indicate corresponding or analogous components. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

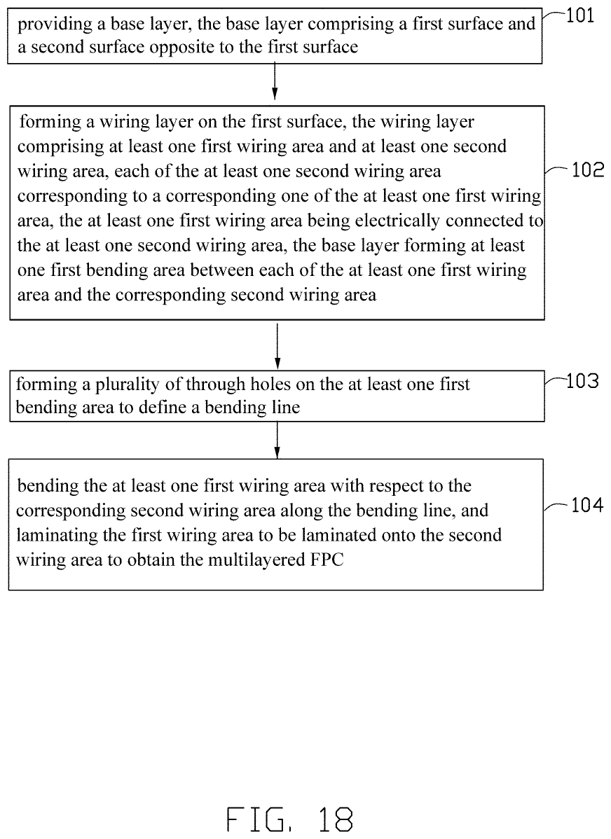

The present disclosure provides a method for manufacturing a circuit board for inclusion in a biosensor chip. The method can be used to manufacture a multilayered flexible circuit board (FPC). Referring to FIG. 18, the method for manufacturing a multilayered FPC is presented in accordance with an embodiment. The method is provided by way of example, as there are a variety of ways to carry out the method. The method can begin at block 101.

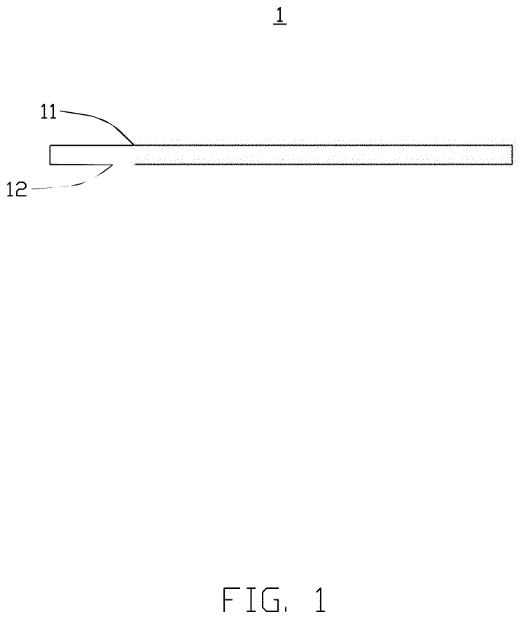

In block 101, referring to FIG. 1, a base layer 1 is provided. The base layer 1 includes a first surface 11 and a second surface 12 opposite to the first surface 11.

In an embodiment, the base layer 1 is made of an insulating resin, such as polyphenylene oxide (PPO), polyimide (PI), polyethylene terephthalate (PET), and polyethylene naphthalate (PEN).

In an embodiment, the base layer 1 is made of PI or PET.

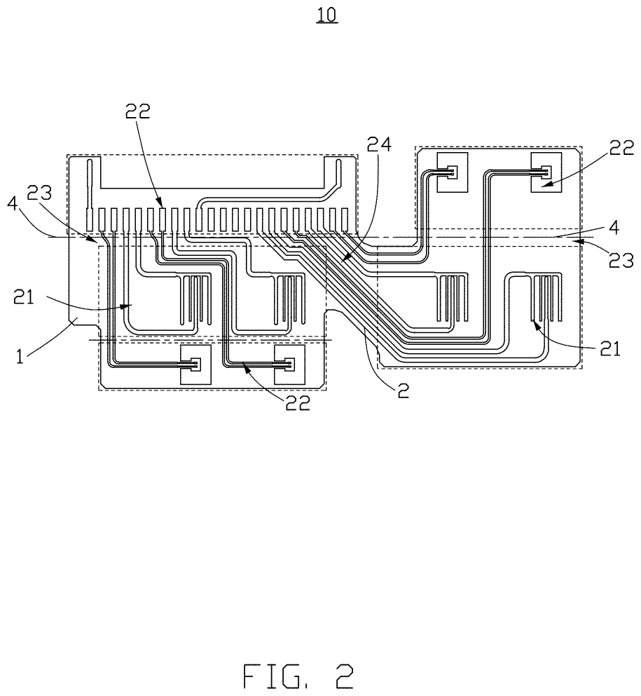

In block 102, referring to FIG. 2, a wiring layer 2 is formed on the first surface 11. The wiring layer 2 includes at least one first wiring area 21 and at least one second wiring area 22 corresponding to the at least one first wiring area 21. The first wiring area 21 is electrically connected to the second wiring area 21. The base layer 1 forms a first bending area 23 between each first wiring area 21 and the corresponding second wiring area 22.

In an embodiment, a second bending area 24 is formed between two adjacent first wiring areas 21. The two adjacent first wiring areas 21 are electrically connected together through the second bending area 24. Some of first wiring area 21 corresponds to one second wiring area 22.

In an embodiment, the wiring layer 2 is formed by printing and a conductive paste cured onto the first surface 11 of the base layer 1.

In an embodiment, the conductive paste is made of silver, copper, or carbon.

In an embodiment, the printing method may be plane printing (such as screen printing, pad printing, and inkjet) or 3D printing.

In an embodiment, a line width of the wiring layer 2 ranges from 8 μm˜20 μm, and preferably, ranges from 11 μm˜13 μm.

In an embodiment, a line thickness of the wiring layer 2 may be achieved by printing different layers of the conductive paste according to actual needs.

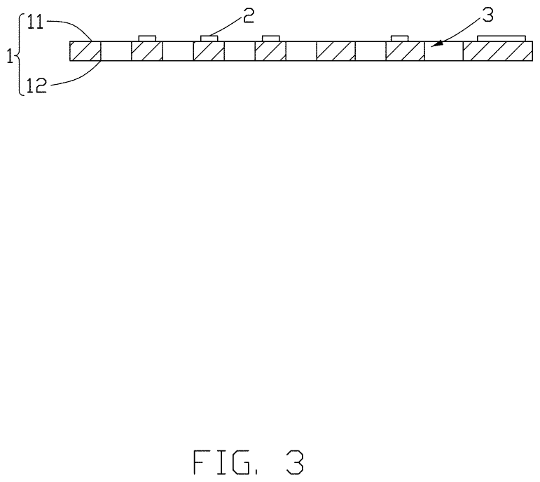

In block 103, referring to FIGS. 2 and 3, a plurality of through holes 3 are formed on the first bending area 23, and the through holes 3 form a bending line 4, to obtain a single-sided FPC.

In an embodiment, the through holes 3 are formed by laser drilling.

In an embodiment, a part of the base layer 1 with the cured conductive paste but which is not needed can be cut off before the through holes 3 are formed on the first bending area 23. The through holes 3 pass through the base layer 1.

In an embodiment, a shape of each through hole 3 may be circular, rectangular, or other shapes. In an embodiment, the shape of each through hole 3 is circular.

In an embodiment, a width of each through hole 3 ranges from 0.05 mm˜0.5 mm. If the width of the through hole 3 is too large, the strength of the multilayered FPC 100 may be reduced. If the width is too small, the flexibility of the first bending area 23 may be reduced.

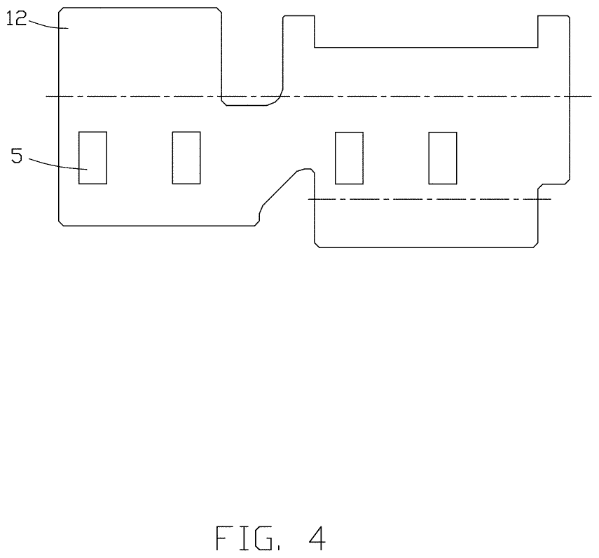

In an embodiment, referring to FIGS. 2 and 4, a functional member 5 is installed on the second surface 12 after forming the through holes 3. The functional member 5 corresponds to at least one of the first wiring area 21 and the second wiring area 22. Then, a two dimensional single-sided FPC 10 is obtained.

By installing the functional member 5 on the second surface 12 without a wiring layer, the functional member 5 does not occupy a space of the first surface 11 and does not affect the wiring layer 2. The installation of the functional member 5 on the second surface 12 without a wiring layer is convenient.

In an embodiment, the functional member 5 may be a heat conducting copper foil or an electromagnetic shielding component. For example, if the functional member 5 is a heat conducting copper foil, the functional member 5 can conduct and dissipate heat of the multilayered FPC 100. If the functional member 5 is an electromagnetic shielding component, the functional member 5 protects against electromagnetic waves.

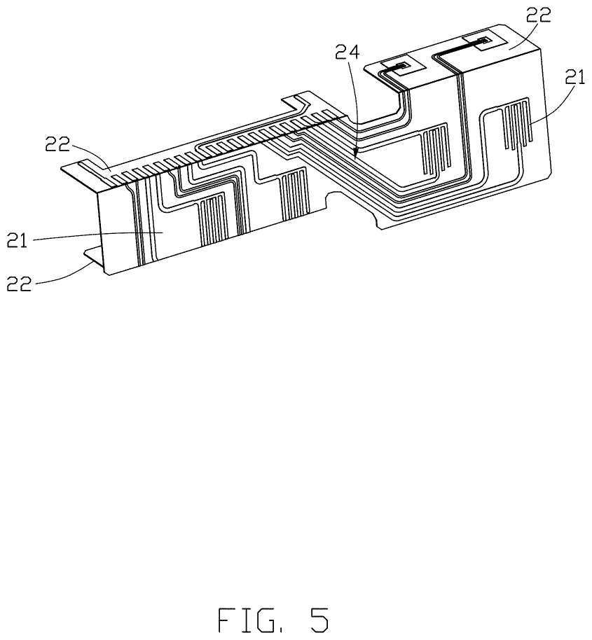

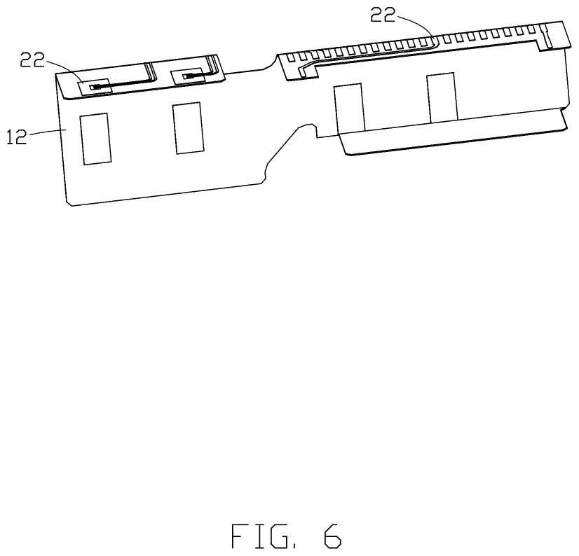

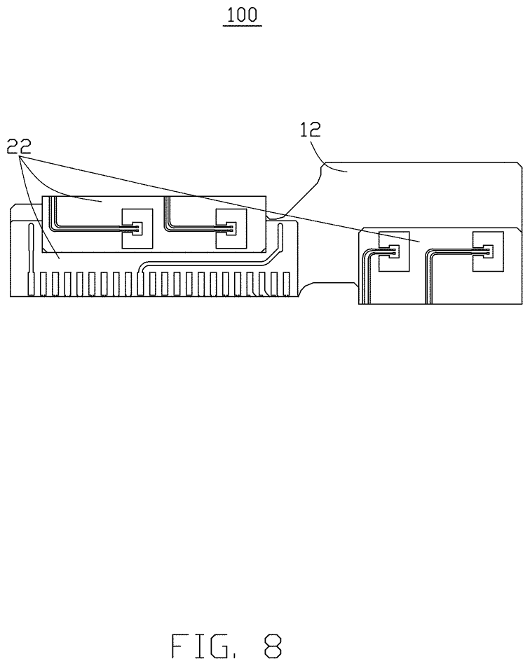

In block 104, referring to FIGS. 5 to 8, the first wiring area 21 is bent along the bending line 4, to laminate the first wiring area 21 on the second wiring area 22, to obtain the multilayered FPC 100.

In the above method, the first wiring area 21 and the second wiring area 22 of the single-sided FPC 10 are folded to form the multilayered FPC (thus a three-dimensional FPC) 100. Since the single-sided FPC 10 can be formed by printing the wiring layer 2 on the base layer 1, the manufacturing process of the single-sided FPC 10 is made simpler, and with high efficiency. Moreover, the shape of the single-sided FPC 10 is not limited and can be according to actual needs. The formation of the through holes 3 allows the first bending area 23 to be laminated on the second wiring area 22 to form the multilayered FPC 100, which will not affect signal transmission of the wiring layer 2. The formation of the through holes 3 also prevents warping of the wiring layer 2, and separation of the wiring layer 2 from the base layer 1.

In an embodiment, referring to FIGS. 5 to 8, the single-sided FPC 10 includes a plurality of second wiring areas 22. The second surface 12 corresponding to the first wiring area 21 and the second surface 12 corresponding to one second wiring area 22 are bonded together, and then the second surface 12 bonded to the second wiring area 22 is laminated and bonded in turn on the wiring layer 2 of the previous second wiring area 22, so as to obtain the multilayered FPC 100. During a bending event, if there is one second wiring area 22 around each first wiring area 21, the first wiring area 21 and the corresponding second wiring area 22 are layered to form the multilayered FPC 100. In the subsequent application process, first wiring areas 21 (including the first wiring area 21 overlapped with the second wiring area 22) all electrically connected with each other can be placed on different application planes. The application planes can be located on one plane or in different planes. When the first wiring areas 21 are in different planes, the second bending area 24 can be freely bent. The multilayered FPC 100 replaces multiple independent circuit boards in a device, reducing the complexity of circuitry.

In an embodiment, the single-sided FPC 10 includes two first wiring areas 21. A second bending area 24 is formed between two adjacent first wiring areas 21. The two adjacent first wiring areas 21 are electrically connected together through the second bending area 24.

In an embodiment, the first wiring area 21 and the second wiring area 22 can be bonded by an adhesive (such as PET double-sided adhesive, PI double-sided adhesive, UV curing adhesive, or pressure-sensitive adhesive). The adhesive can be cured such as by thermal curing, pressure-sensitive curing, or UV curing to obtain the multilayered FPC 100.

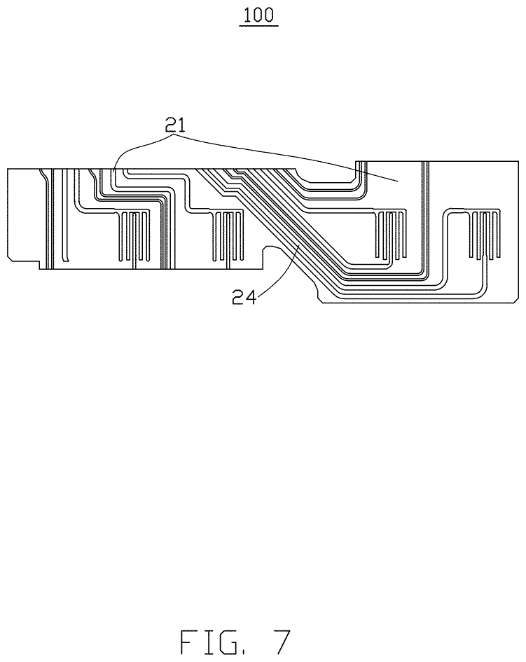

FIG. 7 illustrates an embodiment of a multilayered FPC 100. Referring to FIGS. 2, 3, and 8, the multilayered FPC 100 includes a base layer 1, a wiring layer 2, and through holes 3. The base layer 1 includes a first surface 11 and a second surface 12 opposite to the first surface 11. The wiring layer 2 is disposed on the first surface 11. The wiring layer 2 includes at least one first wiring area 21 and at least one second wiring area 22 electrically connected to the first wiring area 21. The base layer 1 forms a first bending area 23 between each first wiring area 21 and the corresponding second wiring area 22. The through holes 3 are formed on the first bending area 23, and the through holes 3 form a bending line 4. The first wiring area 21 is bent along the bending line 4, causing the first wiring area 21 to be laminated on the second wiring area 22.

In an embodiment, a functional member 5 is installed on the second surface 12. The functional member 5 corresponds to at least one of the first wiring area 21 and the second wiring area 22.

In an embodiment, a width of each through hole 3 ranges from 0.05 mm˜0.5 mm.

In an embodiment, the base layer 1 is made of an insulating resin, such as polyphenylene oxide (PPO), polyimide (PI), polyethylene terephthalate (PET), and polyethylene naphthalate (PEN).

In an embodiment, the multilayered FPC 100 includes a plurality of first wiring areas 21. A second bending area 24 is disposed between two adjacent first wiring areas 21. The two adjacent first wiring areas 21 are electrically connected together through the second bending area 24.

Resistances of the single-sided FPCs 10 with different base layer 1 were analyzed. The same-thickness base layers 1 of the single-sided FPCs 10 are made of PET and PI. The wiring layer 2 is a silver wiring layer. A comparative example uses an FPC with copper wiring layer.

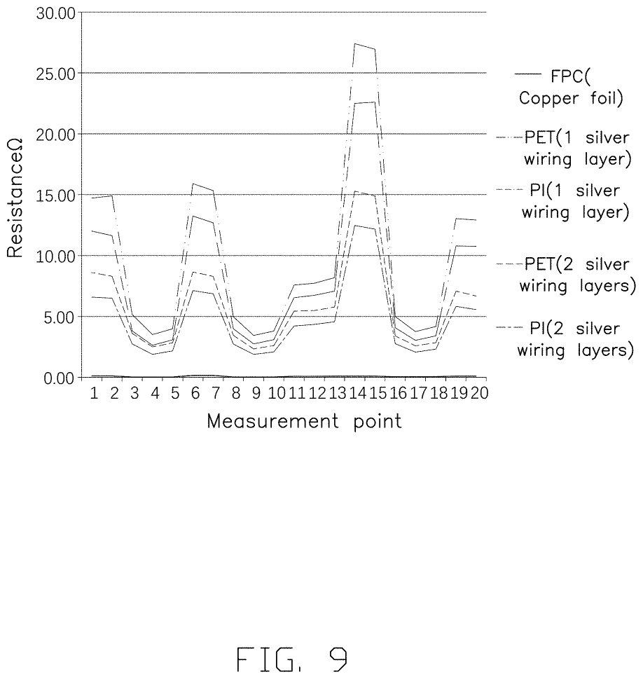

FIG. 9 illustrates the resistances when the line thicknesses of the single-sided FPCs in the present disclosure are changed, compared to the existing FPC with different base layers. Referring to the FIG. 9, the resistances of the single-sided FPCs with the same base layer (such as PET or PI) decrease when the line thicknesses increase. For different base layer (such as PET and PI), the resistances of the single-sided FPCs with the same line thickness are different. The resistance of the single-sided FPC with PI as the base layer is smaller than that of the single-sided FPC with PET as the base layer, thus the electrical performance of the base layer clearly has an impact on the resistance of the single-sided FPC. The electrical performance of PI is better than that of PET. Therefore, when PI is selected as the base layer of the single-sided FPC, the electrical performance of the single-sided FPC is excellent. The resistance of the single-sided FPC in the present disclosure is slightly higher than that of the existing FPC, and the resistance of the single-sided FPC can fully meet the use requirement of the multilayered FPC 100. Overall performance of the multilayered FPC 100 also meets the requirements of actual use. Compared with the existing FPC, the preparation process of the single-sided FPC is simple, the cost is low, and the single-sided FPC is very suitable for products which are disposable.

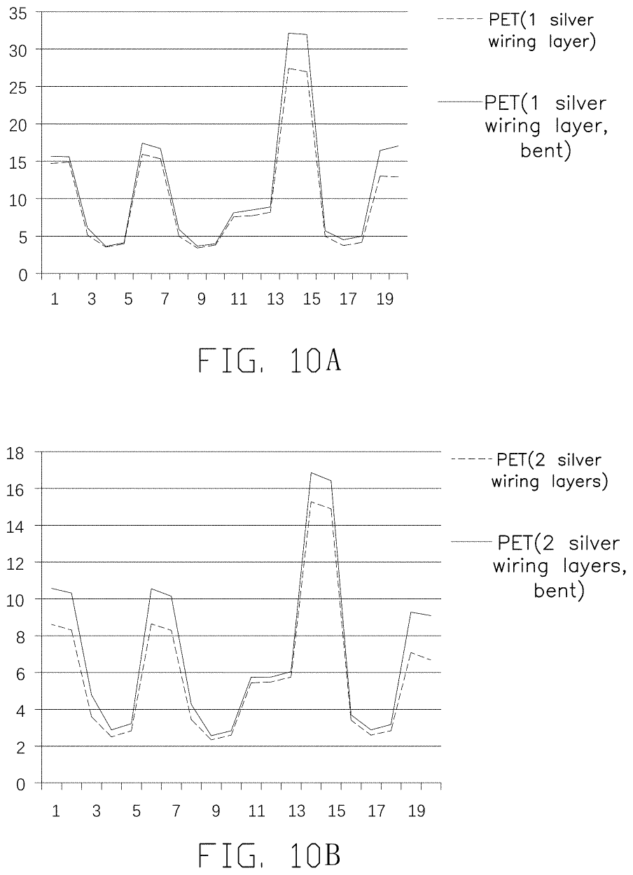

FIG. 10A illustrates the resistances of the single-sided FPC with one wiring layer (such as silver wiring layer) on PET before and after being bent. FIG. 10B illustrates the resistances of the single-sided FPC with two-layered wiring layers (such as silver wiring layers) on PET before and after being bent. FIG. 10C illustrates the resistances of the single-sided FPC with one wiring layer (such as silver wiring layer) on PI before and after bending. FIG. 10D illustrates the resistances of the single-sided FPC with two-layered wiring layers (such as silver wiring layers) on PI before and after being bent. Referring to FIGS. 10A and 10B, the resistance of the bending single-sided FPC with one wiring layer on PET increases by 12.09%, and the resistance of the bending single-sided FPC with two-layered wiring layers on PET increases by 16.53%. Referring to FIGS. 10C and 10D, the resistance of the single-sided FPC with one wiring layer on PI after bending is 1.11% higher, and the resistance of the single-sided FPC with two-layered wiring layers on PI after bending is 3.95% higher. Thus, for the same base layer and the same line thickness, the resistance of single-sided FPC after bending is slightly higher, but this has little impact on the function of the single-sided FPC. Especially for the single-sided FPC with one wiring layer on PI base layer, the resistances are almost the same before and after being bent.

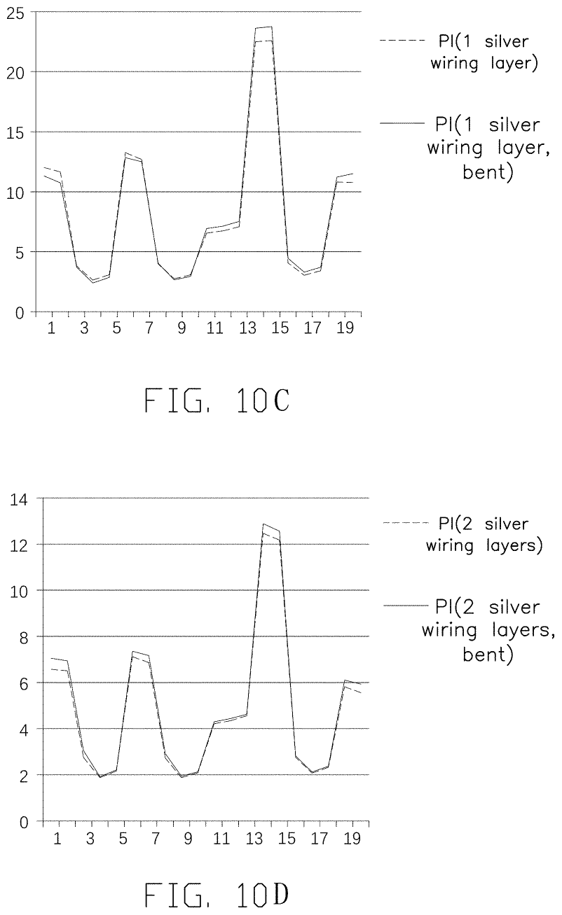

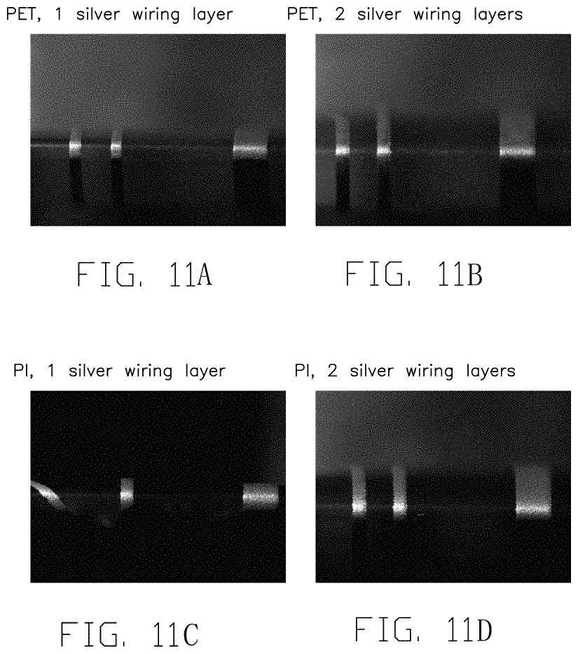

FIGS. 11A to 11D show the bending areas without the through holes of the single-sided FPCs, with different base layers and different line thicknesses. FIGS. 12A to 12C show the bending areas of the single-sided FPC (PET as the base layer) before and after bending.

Referring to FIGS. 10A to 12C, for the single-sided FPCs with PET and PI as the base layers, the wiring layers on the bending areas are not separated from the base layers, and the wiring layers on the bending areas are not cracked. However, there are increased risks of creases occurring on the bending areas of the single-sided FPCs with PET as the base layers, compared to the single-sided FPCs with PI as the base layers. The increase in resistance of the single-sided FPCs with PET as the base layers after bending may be related to creases in the PET base layers after being bent. This also shows that bend-resistance of the base layer has an impact on the resistance of the single-sided FPC. When using PET as the base layer, product yield may be reduced due to creases formed in the PET after being bent. Compared to PET, creases in PI as the base layer do not occur after being bent, product yield is higher, and the electrical performance is also improved.

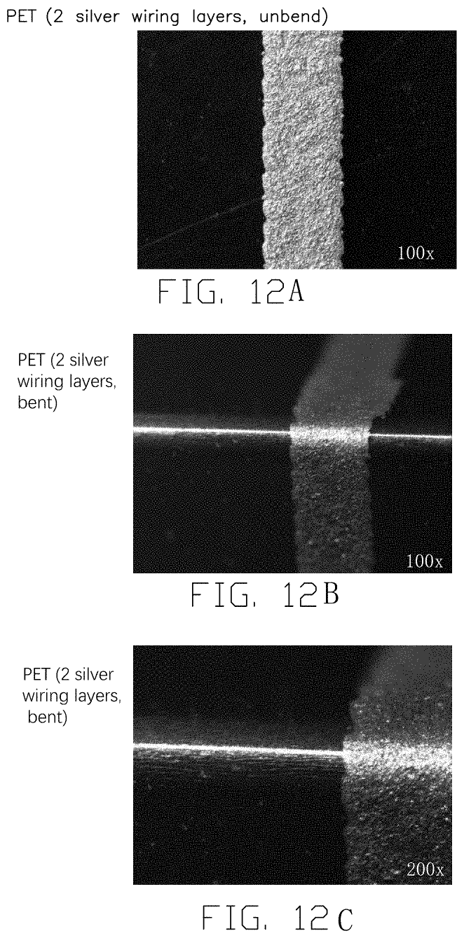

Referring to FIG. 13, the percentage change in resistance of the single-sided FPC (with PET as the base layer) without the through holes after being bent is 12.90% higher. In an embodiment, the percentage change in resistance of the single-sided FPC (with PET as the base layer) with the through holes after being bent is 12.03% higher. In another embodiment, the percentage change in resistance of another single-sided FPC (with PET as the base layer) with the through holes after being bent is 14.02% higher. The change in resistance of the single-sided FPC with and without the through holes is not obvious, indicating that the through holes have little effect on the resistance of the single-sided FPC.

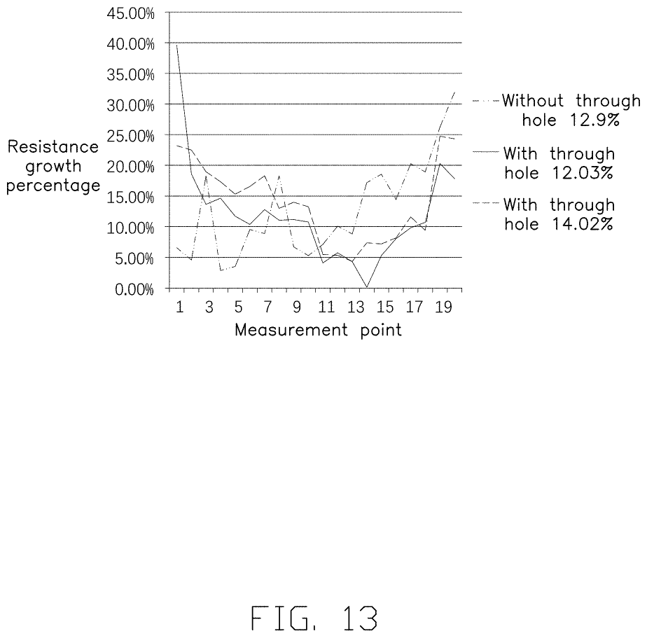

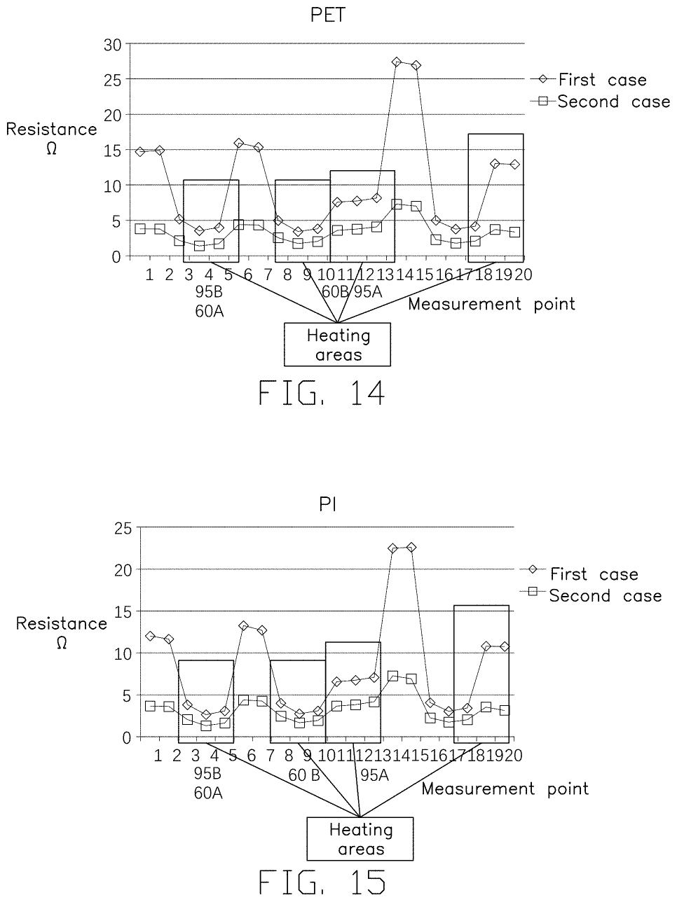

Referring to FIG. 14, the two single-sided FPCs use PET as the base layers. In a first case, the line width ranges from 8 μm-10 μm, and in a second case, the line width ranges from 11 μm-13 μm. Referring to FIG. 15, the two single-sided FPCs use PI as the base layers. In a first case, the line width ranges from 8 μm-10 μm, and in a second case, the line width ranges from 11 μm-13 μm. Referring to FIGS. 14 and 15, the resistance decreases with the increase of the line width. Referring to FIG. 2, the line width of the wiring layer 2 of the single-sided FPC ranges from 8 μm-20 μm. The line width of the wiring layer 2 can be adjusted according to the actual needs.

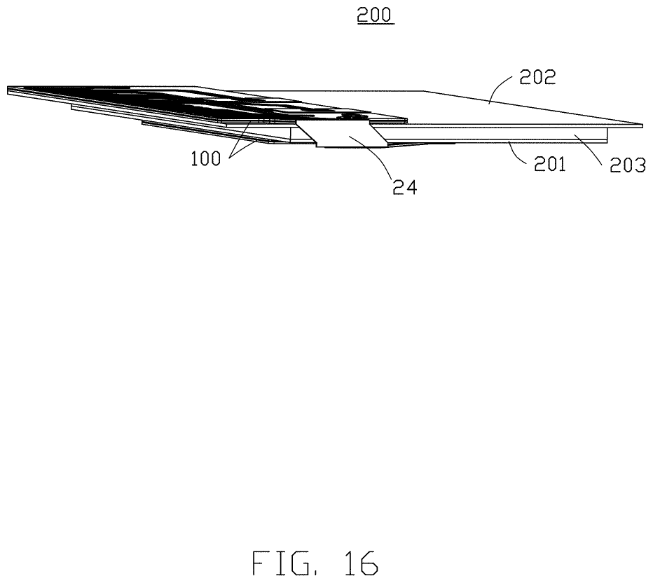

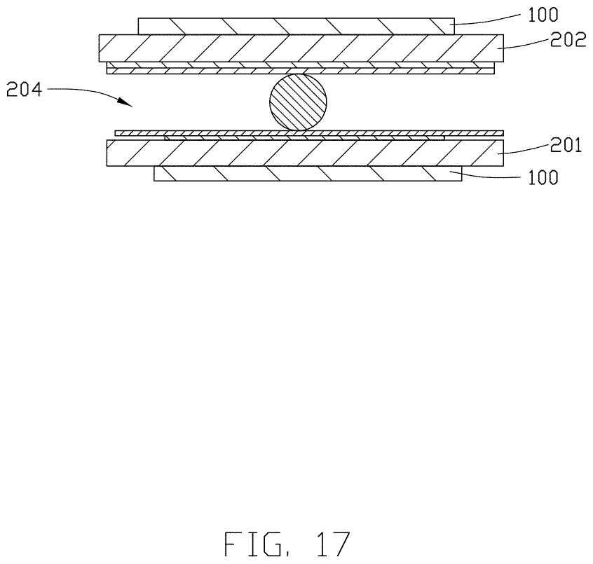

FIG. 16 illustrates a nucleic acid detection chip 200 according to the present disclosure. The nucleic acid detection chip 200 includes a first cover plate 201, a spacer layer 203, a second cover plate 202, and the multilayered FPC 100. Referring to FIGS. 16 and 17, opposite surfaces of the spacer layer 203 are in contact with the first cover plate 201 and the second cover plate 202 respectively. The first cover plate 201, the spacer layer 203, and the second cover plate 202 cooperatively define a channel 204. The multilayered FPC 100 is disposed on a surface of the first cover plate 201 away from the channel 204 and/or the second cover plate 202, away from the channel 204.

In an embodiment, the multilayered FPC 100 can be bonded on the surface of the first cover plate 201 and/or the surface of the second cover plate 202 by an adhesive layer (not shown).

In an embodiment, the multilayered FPC 100 can be bonded on the surface of the first cover plate 201 and/or the surface of the second cover plate 202 by double-sided tape (such as a heat-conductive double-sided tape).

In an embodiment, referring to FIGS. 2, 16 and 17, the multilayered FPC 100 incudes two first wiring areas 21. One second bending area 24 is disposed between the two first wiring areas 21. Each of the first wiring areas 21 corresponds to two second wiring areas 22. One first wiring area 21 and the two corresponding second wiring areas 22 are disposed on the surface of the first cover plate 201 away from the channel 204. The other first wiring area 21 corresponds to one second wiring area 22. The other first wiring area 21 and the corresponding second wiring area 22 are disposed on the surface of the second cover plate 202 away from the channel 204. The multilayered FPC 100 can heat the channel 204. The multilayered FPC 100 heats the channel 204 on opposite sides which provides even heating of the channel 204. In addition, the electrical connection of the two first wiring area 21 is realized through the second bending area 24. The first wiring area 21, the second wiring area 22, and the second bending area 24 being an integrated structure allow convenient assembly of the multilayered FPC 100 in the nucleic acid detection chip 200. Furthermore, wirings to inputs/outputs are only on one of the two first wiring areas 21, convenient for connecting to a power supply and saving installation space of the multilayered FPC 100.

With the above configuration, the single-sided FPC (a two-dimensional FPC) 10 are folded and bonded together to form the multilayered FPC (a three-dimensional FPC) 100. The forming process of the multilayered FPC 100 is simple, the forming cycle is short, and the forming efficiency is high. The format of the multilayered FPC 100 is not limited and is suitable for disposability.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure, up to and including the full extent established by the broad general meaning of the terms used in the claims.

What is claimed is:

1. A method for manufacturing a multilayered flexible circuit board (FPC), comprising:
providing a base layer, the base layer comprising a first surface and a second surface opposite to the first surface;
forming a wiring layer on the first surface, the wiring layer comprising at least one first wiring area and at least one second wiring area, each of the at least one second wiring area corresponding to a corresponding one of the at least one first wiring area, the at least one first wiring area being electrically connected to the at least one second wiring area, the base layer forming at least one first bending area between each of the at least one first wiring area and the corresponding second wiring area;
forming a plurality of through holes on the at least one first bending area to define a bending line; and
bending the at least one first wiring area with respect to the corresponding second wiring area along the bending line, and laminating the first wiring area onto the second wiring area to obtain the multilayered FPC.

2. The method of claim 1, wherein the wiring layer is formed by printing and curing conductive paste on the first surface.

3. The method of claim 2, wherein the conductive paste is made of silver, copper, or carbon.

4. The method of claim 1, wherein a line width of the wiring layer ranges from 8 μm˜20 μm.

5. The method of claim 1, after forming the wiring layer or forming the plurality of through holes, the method further comprising:
disposing a functional member on the second surface, the functional member being positioned corresponding to the at least one first wiring area and/or the at least one second wiring area.

6. The method of claim 1, wherein a width of each of the plurality of through holes ranges from 0.05 mm to 0.5 mm.

7. The method of claim 1, wherein the plurality of through holes is formed by laser drilling.

8. The method of claim 1, wherein the wiring layer comprises at least two first wiring areas, the at least two first wiring areas are electrically connected to each other, and the at least one second bending area is formed between two adjacent of the at least two first wiring areas.

9. The method of claim 1, wherein the base layer is made of an insulating resin selected from a group consisting of polyphenylene oxide (PPO), polyimide (PI), polyethylene terephthalate (PET), and polyethylene naphthalate (PEN).

10. A multilayered flexible circuit board (FPC), comprising:
a base layer;
a wiring layer; and
a plurality of through holes;
wherein the base layer comprises a first surface and a second surface opposite to the first surface, the wiring layer is disposed on the first surface, the wiring layer comprises at least one first wiring area and at least one second wiring area, each of the at least one second wiring area corresponds to a corresponding one of the at least one first wiring area, the at least one first wiring area is electrically connected to the at least one second wiring area, the base layer comprises at least one first bending area between each of the at least one first wiring area and the corresponding second wiring area, the plurality of through holes are formed on the at least one first bending area, and a bending line is defined by the plurality of through holes, the at least one first wiring area are bent with respect to the corresponding second wiring area along the bending line to cause the first wiring area to be laminated on second wiring area.

11. The multilayered FPC of claim 10, wherein a line width of the wiring layer ranges from 8 μm˜20 μm.

12. The multilayered FPC of claim 10, further comprising a functional member on the second surface, wherein the functional member corresponds to the at least one first wiring area and/or the at least one second wiring area.

13. The multilayered FPC of claim 10, wherein a width of each of the plurality of through holes ranges from 0.05 mm to 0.5 mm.

14. The multilayered FPC of claim 10, wherein the wiring layer comprises at least two first wiring areas, the at least two first wiring areas are electrically connected to each other, and a second bending area is formed between two adjacent of the at least two first wiring areas.

15. The multilayered FPC of claim 10, wherein the base layer is made of an insulating resin selected from a group consisting of polyphenylene oxide (PPO), polyimide (PI), polyethylene terephthalate (PET), and polyethylene naphthalate (PEN).

16. A nucleic acid detection chip, comprising:
a first cover plate;
a spacer layer;
a second cover plate; and
a multilayered flexible circuit board (FPC), comprising:
a base layer;
a wiring layer; and
a plurality of through holes;
wherein the base layer comprises a first surface and a second surface opposite to the first surface, the wiring layer is disposed on the first surface, the wiring layer comprises at least one first wiring area and at least one second wiring area, each of the at least one second wiring area corresponds to a corresponding one of the at least one first wiring area, the at least one first wiring area is electrically connected to the at least one second wiring area, the base layer forms at least one first bending area between each of the at least one first wiring area and the corresponding second wiring area, the plurality of through holes are formed on the at least one first bending area, and a bending line is defined by the plurality of through holes, the at least one first wiring area and the corresponding second wiring area are bent and layered along the bending line;
wherein two opposite surfaces of the spacer layer are in contact with the first cover plate and the second cover plate, respectively, the first cover plate, the spacer layer, and the second cover plate cooperatively define a channel, the multilayered FPC is disposed on a surface of the first cover plate away from the channel and/or on a surface of the second cover plate away from the channel.

17. The nucleic acid detection chip of claim 16, wherein a line width of the wiring layer ranges from 8 μm˜20 μm.

18. The nucleic acid detection chip of claim 16, further comprising a functional member on the second surface, wherein the functional member corresponds to the at least one first wiring area and/or the at least one second wiring area.

19. The nucleic acid detection chip of claim 16, wherein a width of each of the plurality of through holes ranges from 0.05 mm to 0.5 mm.

20. The nucleic acid detection chip of claim 16, wherein the wiring layer comprises two first wiring areas, the two first wiring areas are electrically connected to each other, one of the two first wiring areas is disposed on the surface of the first cover plate, the other one of the two first wiring areas is disposed on the surface of the second cover plate, and a second bending area is formed between the two first wiring areas.
